(19) United States
(12) Patent Application Publication
(10) Pub. No.: US 2004/0263178 A1
(43) Pub. Date: Dec. 30, 2004

(54) Diagnostic safety inspection apparatus

(76) Inventor: Tracy C. Klaus, Calgary (CA)

Correspondence Address: SEAN W. GOODWIN, 237- 8TH AVE. S.E., SUITE 360, THE BURNS BUILDING, CALGARY, AB, T2G 5C3, CA

(21) Appl. No.: 10/602,858

(22) Filed: Jun. 25, 2003

(51) Int. Cl. G01R 31/00

(52) U.S. Cl. 324/504

(57) ABSTRACT

An improved diagnostic device for inspecting the pneumatic braking systems and electrical signaling systems on a cargo hauling trailer comprises a unique circuit arrangement permitting a single inspector to inspect the pneumatic braking systems and when required, override diagnostic cycling of the brakes between applied and released states to an alternate diagnostic wherein the system is continuously supplied with air to permit leak detection. A solenoid, normally cycling air to the pneumatic braking systems under the control of a programmable timer, can be overridden and powered to supply continuous air, regardless of the state of the timer, by actuating a brake light circuit which is connected to the solenoid through a pressure actuated switch.

### FIELD OF THE INVENTION

The invention relates to diagnostic devices for performing safety inspections on cargo trailers and more particularly to performing testing of electrical circuits and air pressure circuits for braking systems.

### BACKGROUND OF THE INVENTION

Commercial cargo hauling trailers are equipped with numerous safety and signaling features. Typically trailers are equipped with brake lights, turn signals, tail lights, marker lights which are located at the top and along the length of the trailer to indicate the extent of the trailer and an ABS warning light. Typical safety systems include pneumatic braking systems, often augmented with an ABS system, for both primary braking and emergency braking. During prolonged use, electrical circuits which operate the signaling systems, and pneumatic lines connected to the braking systems, are subject to wear and tear which may compromise their integrity.

Most countries have regulations, such as those of the US Department of Transport and Transport Canada, which require regular, scheduled inspection of all electrical circuits which power the signaling systems and pressurized air systems which are integral to the braking systems on all commercial trailer units.

It is a well known practice to require two inspectors to check the trailer systems. Typically, the trailer is connected to a towing vehicle, such as a tractor, in order to supply power and air to the systems. A first inspector sits in the cab of the tractor and applies all of the systems while a second inspector moves about the periphery of the trailer observing the operation of the various signaling devices and listens for air leaks and the like in the pneumatic lines connected to the brakes. This process is labor intensive and costly, requiring two individuals and necessitates coupling each trailer to be inspected to a towing vehicle, prior to inspection.

Others have attempted to provide diagnostic devices which can be operated by a single inspector without requiring a towing vehicle. One such diagnostic device is taught in U.S. Pat. No. 6,323,651 to Melendez. The device plugs into the electrical connector of a trailer and permits a single inspector to selectively check illumination and signaling circuits on the trailer as well as periodically actuating the pneumatic system of the trailer at pre-selected intervals. Each trailer circuit is connected to a separate control switch on a housing which has a visual indicator to indicate whether the circuit is functioning properly. Further, the housing is connected to the primary and emergency pneumatic lines on the trailer and has a valve connected to a timer which cycles the pneumatic brake systems on and off at preset time intervals while the operator or inspector checks for air leaks and lubricates and adjusts the brakes. Applicant believes that the preset interval between activation and deactivation of the pneumatic brakes is insufficient, either to locate a non-obvious air leak or to effect lubrication and the like.

A remote control device for enabling point by point inspection is taught in U.S. Pat. No. 6,154,035 to Aguirre et al. A main unit is coupled to a power source, a source of pressurized air and to the trailer. A receiver module is incorporated into the main unit for receiving information transmitted from a hand held remote control device. Commands from the remote control device act to active and deactivate switches from an open to a closed state to test the various electronic systems on the trailer. A pneumatic valve which controls air flow to the pneumatic brake systems can be remotely switched from an off-state to an on-state to permit inspection of the air-brake application and release. Applicant's experience with hand-held remote transmitters is that the transmitter is often easily misplaced or damaged through rough handling in use or when stored in a vehicle or tool box.

Clearly, what is required is a robust portable diagnostic device that can be easily connected to a trailer for testing electronic circuits and braking systems that can be operated, particularly with regards to the brakes, in a variety of ways in order to provide the inspector with maximum flexibility to diagnose and affect repairs to both the signaling and the braking systems.

### SUMMARY OF THE INVENTION

The present invention is an improved diagnostic device for use by a single inspector in inspecting commercial cargo-hauling trailers. The device comprises pneumatic and electrical circuitry and particularly, a unique enhanced circuit connecting a programmable timer circuit, which cycles the pneumatic braking systems on the trailer between an applied state and a released state using a solenoid, to a brake light circuit connected to the solenoid through a pressure actuated switch. Actuation of the brake light circuit, when the system is charged with air, causes the solenoid to be powered through the pressure actuated switch thus overriding the cycling of the braking systems to apply a continuous stream of air to the brakes permitting detection of leaks. Thus, the inspector can simply flip a toggle switch connected to the brake light circuit on the diagnostic device each time he wishes to alter the state of pneumatic braking systems on the trailer.

In a broad aspect of the invention, the improved diagnostic device comprises: a pneumatic circuit adapted for connection to pneumatic braking systems on the trailer; means such as a solenoid responsive to an electrical signal, for cycling the pneumatic circuit between an applied state wherein air is supplied to the trailer's pneumatic braking systems and a released state wherein air is released from the trailer's pneumatic braking systems; an adjustable timer circuit, electrically connected to the means for cycling the pneumatic circuit for controlling a timed interval between the applied state and the released state; a diagnostic brake light circuit adapted for connection to a brake light circuit on the trailer, the diagnostic brake light circuit having a circuit switch operable to transmit an electrical signal in on-state and preferably having an indicator means for connection thereto; and a pressure actuated switch, connected between the means for cycling the pneumatic circuit and the diagnostic brake light circuit, and operable between an electrically conductive state when pressure is applied to the pressure actuated switch and an electrically non-conductive state when pressure is released from the pressure actuated switch, wherein when the pneumatic circuit is in the applied state causing pressure to be applied to the pressure actuated switch and when the diagnostic brake light circuit is in the on-state, the electrical signal from the brake light switch is conducted through the pressure actuated switch to the means for cycling the pneumatic circuit, maintaining the pneumatic circuit in the applied state, regardless of the state of the timer circuit.

Preferably, the circuits are actuated through corresponding toggle switches, presented on a control panel of a housing. Indicator lights, corresponding to each toggle switch, are wired to each circuit and illuminate to indicate operation of each circuit. An infinitely programmable timer, connected to the timer circuit is accessed at the control panel to permit setting of any desired interval between an applied and a released state of the pneumatic braking systems.

The diagnostic device is supplied with air from a source of compressed air connected to the pneumatic circuit within the housing and through an air supply valve within the housing to the trailer's pneumatic braking systems.

Preferably, in a preferred embodiment of the invention, a plurality of electrical circuits having associated toggle switches and indicator lights are also included for inspecting the electrical signaling circuits, such as turn signals, tail lights, marker lights and ABS brake lights.

Advantageously, the diagnostic device is portable and can be mounted in a cart or two-wheeled dolly, including a power supply such as a 12V battery and an air supply, mounted on a mobile service truck or mounted on the wall of a shop for inspection of trailers in a service bay. Air supply lines and electrical connections are sized having a suitable length depending upon the particular mounting arrangement use.

### BRIEF DESCRIPTION OF THE DRAWINGS

FIG. 1 is a perspective view of a an embodiment of a diagnostic device of the present invention illustrating an exterior of the device;

FIG. 2a is a plan view of the exterior control panel according to FIG. 1;

FIG. 2b is a front view of the exterior according to FIG. 1, illustrating power and pneumatic connections;

FIG. 2c is a rear view of the exterior according to FIG. 1;

FIG. 3 is a schematic plan view illustrating a pneumatic circuit housed within the diagnostic device according to FIG. 1;

FIG. 4 is a schematic illustrating the connection between a timer circuit, a brake light diagnostic circuit and a pneumatic circuit housed within the housing according to FIG. 1; and

FIG. 5 is a schematic illustrating a plurality of signaling light, diagnostic circuits housed within the housing according to FIG. 1.

### DETAILED DESCRIPTION OF THE PREFERRED EMBODIMENT

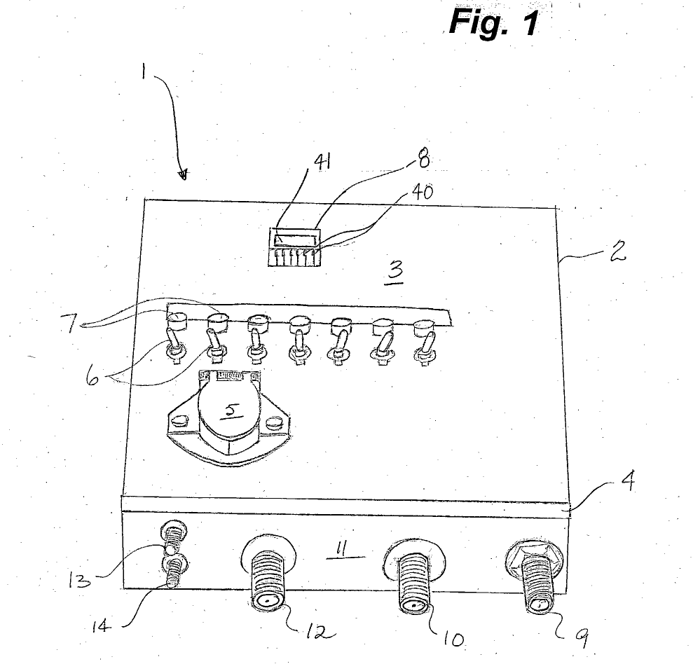

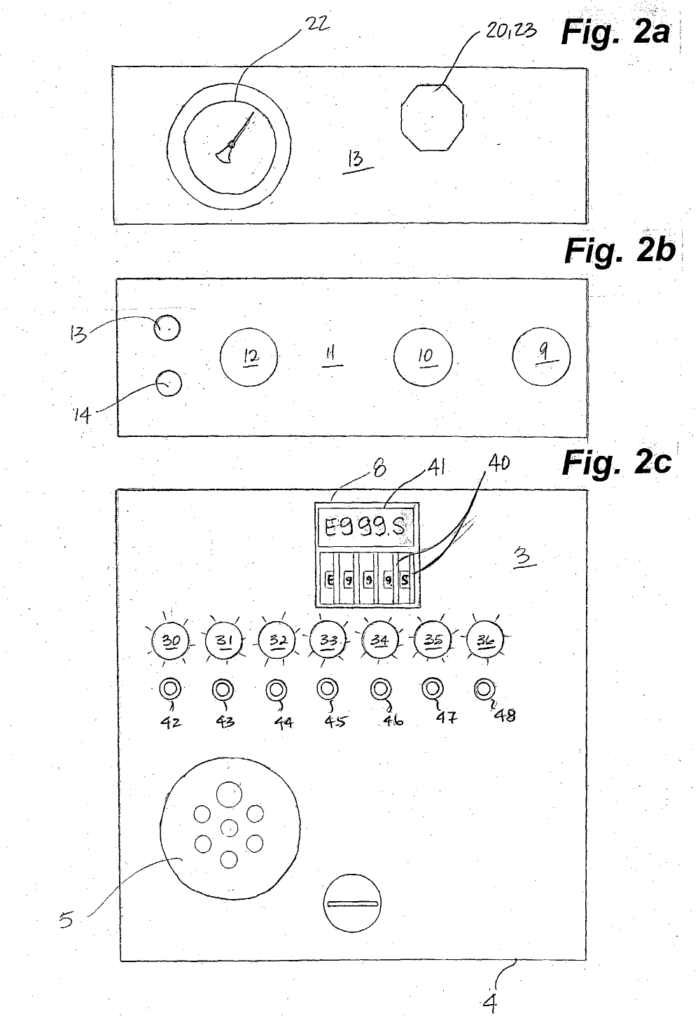

Having reference to FIGS. 1 and 2a-c, one embodiment of an improved diagnostic apparatus 1 is shown for use in inspecting commercial cargo-hauling trailers. The diagnostic apparatus 1 comprises a housing 2 which houses a plurality of electrical circuitry and pneumatic circuitry adapted for connection to a plurality of electrical signaling circuitry and to pneumatic braking systems on the trailer (not shown), which is to be inspected. A control panel 3 on a top 4 of the housing 2 permits an inspector to select individual circuits to be tested.

The control panel 3 has an electrical plug connector 5 into which the trailer electrical receptacle (not shown) is plugged, connecting the diagnostic device 1 to the signaling circuits on the trailer. A series of toggle switches 6 are used to select individual circuits and a series of corresponding incandescent indicator lights or LED's 7 provide visual confirmation of the corresponding circuits operation.

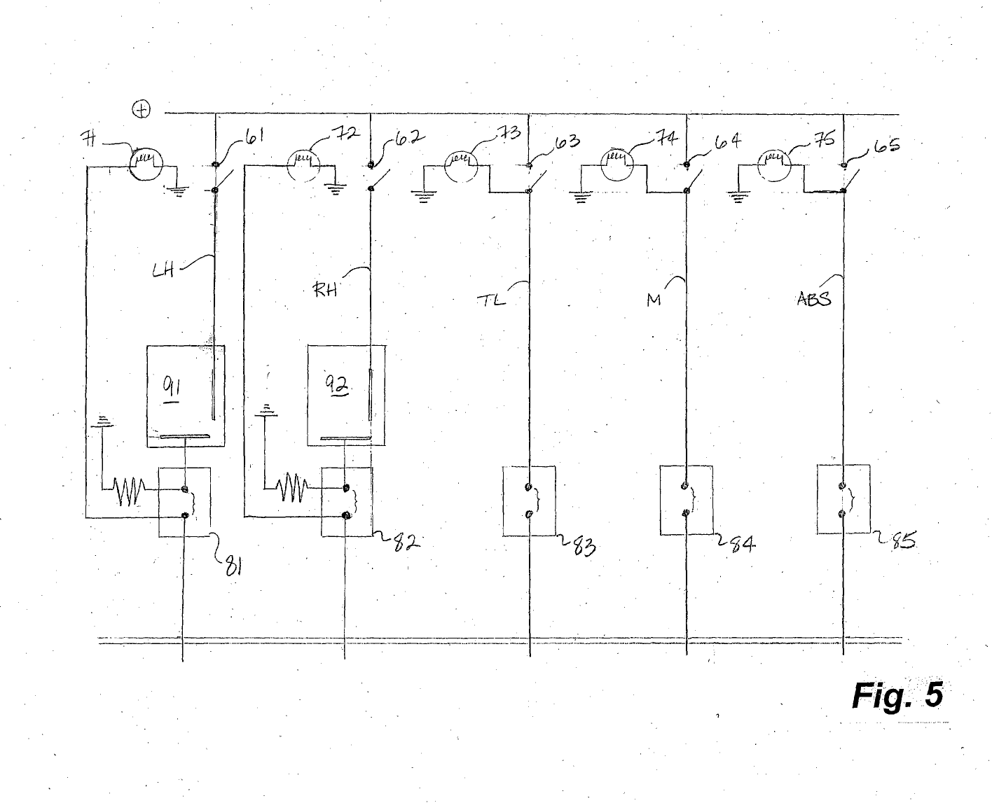

In a preferred embodiment, as seen in FIG. 2a, the indicator lights 7 and corresponding circuitry, best seen in FIG. 5, are arranged conveniently as follows, beginning at the left of the control panel 3: left hand turn signals 30, right hand turn signals 31, tail lights 32, marker lights 33, ABS warning light 34, diagnostic device timer 35 and brake lights 36.

Further, a timer 8 is accessible at the control panel 3 for altering the timing of cycling of pneumatic circuits to permit testing of the braking systems.

Best seen in FIGS. 1 and 2b, pneumatic circuits P comprise a service hose fitting 9 and an emergency hose fitting 10, situated on a front 11 of the housing 2 for connection to corresponding service and emergency pneumatic lines on the trailer. An air inlet 12 is also situated on the front 11 of the housing 2 for connection to an air supply (not shown), such as an air compressor, for providing a source of compressed air to the pneumatic circuits P in the housing 2 and on the trailer. Further, electrical contact posts 13, 14 are provided for connection to a power source (not shown), typically a 12 volt battery, for providing electrical power to the diagnostic device 1 and to the trailer's electrical circuits.

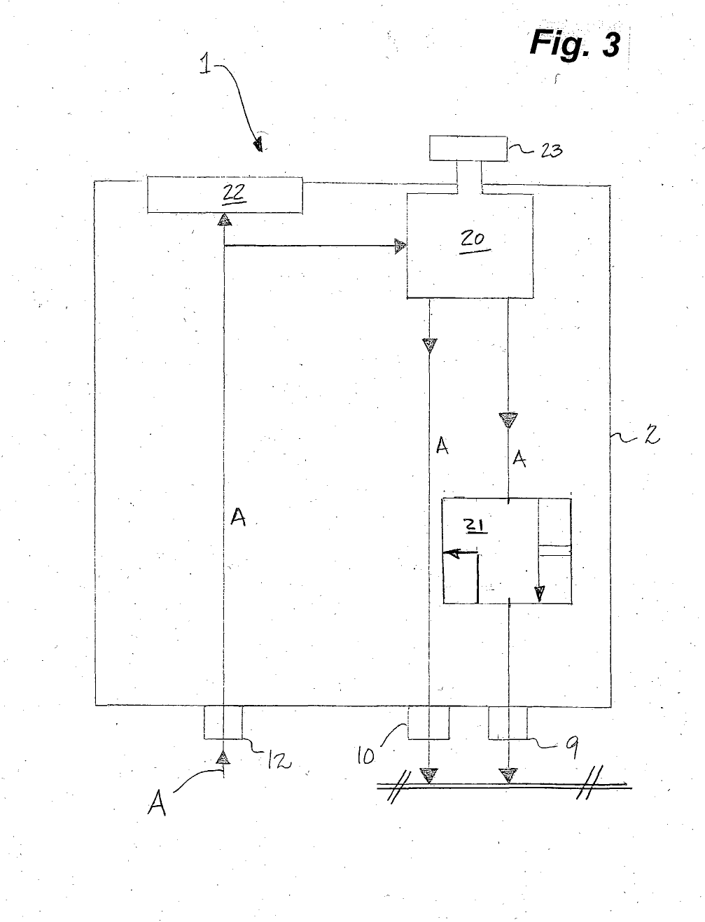

As shown in FIGS. 2c and 3, compressed air A entering the air inlet is supplied to an air supply valve 20 which, on demand, routes the air A directly to the emergency hose fitting 10 and to the emergency hose on the trailer and to means on the pneumatic circuit P for alternating between applied and released states. Means, such as a solenoid 21, are responsive to an electrical signal. The solenoid valve 21 controls flow of air A to supply hose fitting 9 connected to a supply line on the trailer. A pressure gauge 22 situated on a back 13 of the housing 2, is used to indicate the pressure of air A being supplied for testing. Typically, testing is performed using a minimum of 85 psi (586 kPa) and more preferably 100 psi (689 kPa).

A manual air supply knob 23 protrudes from the back of the housing 2 and is connected to the air supply valve 20 to permit charging the emergency line on the trailer through the emergency hose fitting 10 and the solenoid 21 with air A when depressed. Following testing, the air supply knob 23 is released by pulling out, which resets the pneumatic circuit P of the diagnostic device 1.

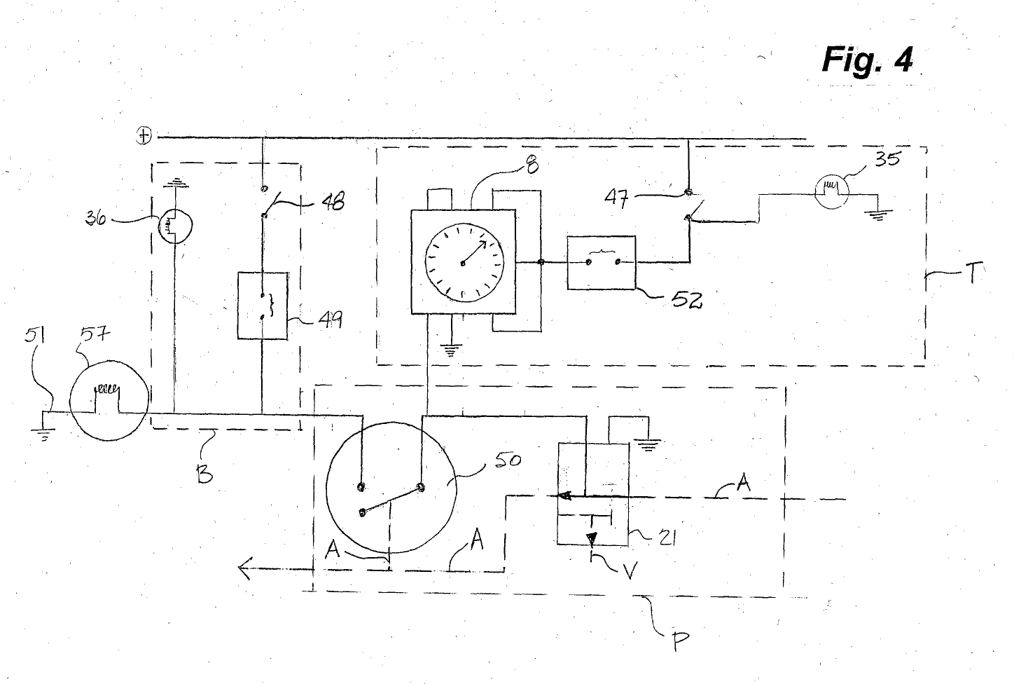

Having reference to FIG. 4, in order to permit testing of the pneumatic braking systems on the trailer, a three-way form of the solenoid 21 supplies compressed air to the trailer's service line, and is controlled by the timer 8 between an applied state in which air A is supplied to the trailer, and a released state in which air A is vented V through the solenoid 21 to atmosphere into the housing 2. Preferably, the timer 8 has an infinitely programmable time selection to permit cycling of the air A to the trailer between the applied state and the released state. A desired interval, sufficient to diagnose and service the braking systems, can be set by the inspector. Thus, the inspector can move about the trailer as the brakes cycle off and on to detect any leakages or to provide service to the brakes. One such timer 8 is a Potter Brumfield CNT 35-26 programmable multifunction digital time delay relay/counter. Time intervals are infinitely programmable between 0.1 sec and 9,990 hours using thumbwheel switches 40, the preset time of each cycle being displayed on a digital display 41. Typically, the timer 8 is set to be programmable between 0.1 and 999 seconds.

A timer circuit T, the pneumatic circuit P and a diagnostic brake light circuit B are shown. The timer 8 is connected to the pneumatic circuit P through solenoid 21. Further, the solenoid 21 is connected to the diagnostic brake light circuit B through a pressure actuated switch 50 which acts alternately between an electrically conductive state and an electrically non-conductive state. The electrically conductive state is achieved as a result of pressure supplied by the pneumatic circuit P. The electrically non-conductive state is achieved when air is not supplied to the pneumatic circuit P.

Accordingly, when the pressure actuated switch 50 is in the electrically conductive state, there is an electrical connection between the solenoid 21 and the diagnostic brake light circuit B. Serendipitously, when testing for air leaks, the diagnostic brake light circuit B can be used to hold the pneumatic circuit P in an applied state without the need for a separate pneumatic circuit. Provided the pneumatic circuit P is charged with air A, and when the brake light toggle switch 48 is turned on, the solenoid 21 is powered through the diagnostic brake light circuit B and acts to apply air to the signaling circuit's brake light 57 on the trailer regardless of the state of the timer 8.

As shown in FIG. 4, this enhanced circuit is achieved as follows. The brake light circuit B comprises a brake light toggle switch 48 which is connected through circuit breaker 49 to the brake light 57 on the trailer when the trailer's electrical receptacle is plugged into the electrical plug connector 5. Further, the brake light toggle switch 48 is also connected to the brake light indicator light 36 on the control panel 3 through circuit breaker 49. Normally, this is used independently to test the brake lights. As stated earlier, the diagnostic brake light circuit B is also connected through the pressure actuated switch 50 to the solenoid 21.

A timer toggle switch 47 is connected to the timer indicator light 35 which is also connected through a circuit breaker 52 to the timer 8. The timer 8 is connected to the solenoid 21. When the timer toggle switch 47 is activated, the timer indicator light 35 acts to indicate that the timer 8 is on and the solenoid 21 cycles between the on-state and the off-state.

Advantageously, as previously described, so as to permit the inspector to seek out subtle air leaks or to perform prolonged servicing of the brake systems, when the pneumatic circuit P is charged with air A, such as when the timer 8 is in the applied state, concurrent activation of the brake light toggle switch 48 conducts a current through the electrically conductive pressure actuated switch 50 to power the solenoid 21 as long as the brake light circuit B is in an on-state. Air A is thus supplied continuously to the brake systems on the trailer, regardless of the state of the timer 8. Similarly, even when the brake light toggle switch 48 and diagnostic brake light circuit B are off, the timer 8 cyclically powers and illuminates the brake light 57 on the trailer and the indicator light 36 each time the pneumatic circuit P is in the applied state and the pressure actuated switch 50 becomes conductive.

Having reference to FIG. 5, additional diagnostic electrical signaling circuits, corresponding to the signal systems on the trailer, are shown. Preferably, the diagnostic device 1 further houses a left hand turn signal circuit LH, a right hand turn signal circuit RH, a tail light circuit TL, a marker light circuit M and an ABS warning light circuit ABS. Each of the aforementioned circuits comprises a toggle switch 61, 62, 63, 64, 65 and a respective indicator light 71 72, 73, 74, 75, each connected to the corresponding circuitry on the trailer through circuit breakers 81, 82, 83, 84, 85. The left and right hand signal circuits LH, RH, further comprise flashers 91, 92 connected between the toggle switches 61, 62 and the circuit breakers 81, 82 to permit testing of the turn signals. The flashers 91, 92 cause the indicator lights 71, 72 to flash when an intermittent power signal is passed from the turn signal circuits on the trailer. Resistors R1, R2 are connected to each of the turn signal circuits LH, RH at the circuit breakers 81, 82.

Preferably, the diagnostic apparatus 1 is mounted on a moveable cart or dolly, service truck or on a wall of a service bay. The air supply and electrical connections are of sufficient length to meet the needs of each different mounting arrangement.

In Use

In a preferred embodiment of the invention, the diagnostic device 1 is connected to the power source, preferably a 12 V battery, and to the trailer by plugging the trailer light cord receptacle (not shown) into the diagnostic device's electrical plug connector 5. Compressed air is supplied to the diagnostic device 1 by connecting the source of compressed air to the air line inlet 12. The emergency and service lines of the trailer are connected to the diagnostic device's emergency hose fitting 10 and the service hose fitting 9, respectively. Thus, when air A is supplied through the inlet 12, the air supply valve 23 can be depressed for charging air directly to the emergency hose fitting 10 and to the solenoid 21. The timer 8 is set to a desired interval and is actuated using the timer toggle switch 47. The timer indicator light 35 is illuminated to indicate that the timer 8 is on. The timer 8 cycles between the applied state, applying or charging air to the pneumatic circuit P and causing the brakes on the trailer to be disengaged, and the released state, wherein air is caused to be released or vented V through the solenoid 21 to atmosphere and causing the brakes to be actuated. The timer 8 continues to cycle between an electrically on-state (pneumatically applied state) and an off-state (pneumatically released state) while the inspector moves about the trailer diagnosing leaks and performing service.

Should the inspector require a continuous supply of air A to the brakes to permit prolonged servicing or diagnosing of subtle air leaks, the brake light toggle switch 48 is actuated simultaneously with a timing cycle wherein the solenoid 21 is in an on-state and the air A is applied. Advantageously, power to be supplied from the diagnostic brake light circuit B and through the pressure actuated switch 50 in the electrically conductive state to the solenoid 21 causes a continuous air supply to the brakes regardless of the state of the timer 8. Switching off the brake light toggle switch 48 and the timer toggle switch 47 causes the solenoid 21 to de-energize and vent V the air A from the trailer service line. Once testing and servicing has been complete the air supply valve can be pulled out to reset the pneumatic circuit P.

TABLE I
Brake, timer and pneumatic circuit states and various outcomes

| Brake light | | Pneumatic | Air A to | | Brake light |
|---|---|---|---|---|---|
| circuit B | Timer Circuit 8 | circuit P | trailer | Brakes cycle | indicator light |
| ON | OFF | OFF | NO | NO | YES |
| ON | ON | ON | YES | NO | YES |
| | | | | continuous air | |
| ON | OFF | ON | YES | NO | YES |
| | | | | continuous air | |
| OFF | ON | ON | YES | YES | YES |

Testing of the signaling systems can be performed by actuating the individual toggle switches 61, 62, 63, 64, 65 of the electrical circuits LH, RH, TL, M, ABS and observing the response at the trailer. While testing can be performed simultaneously by actuating all of the toggle switches 61, 62, 63, 64, 65, it may be advantageous to test each circuit LH, RH, TL, M, ABS individually. This is particularly of importance to ensure that signaling systems such as tail lights 32 and marker lights 33, which are required to be on separate circuits on the trailer, are in fact wired separately. If a single toggle switch 63 or 64 is actuated and both the tail lights 32 and marker lights 33 illuminate, it is easy for the inspector to note and cite the deficiency.

The embodiments of the invention in which an exclusive property or priviledge is claimed are defined as follows:

1. An improved diagnostic apparatus for diagnosing and servicing pneumatic braking systems of trailers comprising:
a pneumatic circuit, adapted for connection to pneumatic braking systems on the trailer;
means, responsive to an electrical signal, for cycling the pneumatic circuit between an applied state wherein air is supplied to the trailer's pneumatic braking systems and a released state wherein air is released from the trailer's pneumatic braking systems;
a timer circuit, electrically connected to the means for cycling the pneumatic circuit for controlling a timed interval between the applied state and the released state, the timed interval being adjustable;
a diagnostic brake light circuit adapted for connection to a brake light circuit on the trailer, the diagnostic brake light circuit having a circuit switch operable to transmit an electrical signal in on-state and having an indicator means for connection thereto; and
a pressure actuated switch, connected between the means for cycling the pneumatic circuit and the diagnostic brake light circuit, and operable between an electrically conductive state when pressure is applied to the pressure actuated switch and an electrically non-conductive state when pressure is released from the pressure actuated switch, wherein
when the pneumatic circuit is in the applied state causing pressure to be applied to the pressure actuated switch and when the diagnostic brake light circuit is in the on-state, the electrical signal from the brake light switch is conducted through the pressure actuated switch to the means for cycling the pneumatic circuit, maintaining the pneumatic circuit in the applied state, regardless of the state of the timer circuit.

2. The improved diagnostic apparatus as described in claim 1, wherein the means for cycling the pneumatic circuit is a solenoid.

3. The improved diagnostic apparatus as described in claim 1, wherein the diagnostic brake light circuit further comprises a circuit breaker, operable between the circuit switch and the electrical brake light circuit on the trailer.

4. The improved diagnostic apparatus as described in claim 1, wherein the timer circuit further comprises:
a circuit switch,
a circuit breaker, operable between the circuit switch and the electrical brake light circuit on the trailer; and
an indicator light for indicating the operation of the timer circuit.

5. The improved diagnostic apparatus as described in claim 1 further comprising a plurality of diagnostic signaling circuits adapted for connection to a plurality of signaling circuits on the trailer.

6. The improved diagnostic apparatus as described in claim 5 wherein each of the plurality of diagnostic signaling circuits further comprises:
a circuit switch; and
an indicator light for indicating the operation of each of the signaling circuits on the trailer.

7. The improved diagnostic apparatus as described in claim 6 wherein the plurality of diagnostic signaling circuits further comprise:
a left turn signal diagnostic circuit;
a right turn signal diagnostic circuit;
a tail light diagnostic circuit;
a marker light diagnostic circuit; and
an ABS brake light diagnostic circuit.

8. The improved diagnostic apparatus as described in claim 7 wherein each of the left and right turn signal diagnostic circuits further comprise a flasher for transmitting an intermittent power signal from corresponding left and right turn signal circuits on the trailer to the diagnostic apparatus.

9. The improved diagnostic apparatus as described in claim 1 wherein the indicator means is an indicator light.

10. The improved diagnostic apparatus as described in claim 9 wherein the indicator light is an LED.

11. An improved diagnostic apparatus for testing electrical and pneumatic systems on a trailer comprising:
a pneumatic circuit, adapted for connection to pneumatic braking systems on the trailer;
means, responsive to an electrical signal, for cycling the pneumatic circuit between an applied state wherein air is supplied to the trailer's pneumatic braking systems and a released state wherein air is released from the trailer's pneumatic braking systems;
a timer circuit, electrically connected to the means for cycling the pneumatic circuit for controlling a timed interval between the applied state and the released state, the timed interval being adjustable;
a diagnostic brake light circuit adapted for connection to a brake light circuit on the trailer, the diagnostic brake light circuit having a circuit switch operable to transmit an electrical signal in on-state and having an indicator means for connection thereto;
a plurality of diagnostic signaling circuits each circuit adapted for connection to signaling circuits on the trailer, each diagnostic signaling circuit having a circuit switch means, operable between an off-state and an on-state and having an indicator means for connection thereto; and
a pressure actuated switch, connected between the means for cycling the pneumatic circuit and the diagnostic brake light circuit, and operable between an electrically conductive state when pressure is applied to the pressure actuated switch and an electrically non-conductive state when pressure is released from the pressure actuated switch,
wherein when the pneumatic circuit is in the applied state causing pressure to be applied to the pressure actuated switch and when the diagnostic brake light circuit is in the on-state, the electrical signal from the brake light switch is conducted through the pressure actuated switch to the means for cycling the pneumatic circuit, maintaining the pneumatic circuit in the applied state, regardless of the state of the timer circuit.

12. The improved diagnostic apparatus as described in claim 11, wherein the means for cycling the pneumatic circuit is a solenoid

13. The improved diagnostic apparatus as described in claim 11 wherein the plurality of diagnostic signaling circuits further comprise:
a left turn signal diagnostic circuit;
a right turn signal diagnostic circuit;
a tail light diagnostic circuit;
a marker light diagnostic circuit; and
an ABS brake light diagnostic circuit.

14. The improved diagnostic apparatus as described in claim 13 wherein the left and right turn signal diagnostic circuits further comprise a flasher capable of transmitting an intermittent power signal from corresponding left and right turn signal circuits on the trailer to the diagnostic apparatus.

15. The improved diagnostic apparatus as described in claim 11, wherein the timer circuit and each diagnostic signaling circuit further comprises a circuit breaker, operable between the circuit switch and the corresponding signaling light circuit on the trailer.

16. The improved diagnostic apparatus as described in claim 11 wherein the indicator means are indicator lights.

17. The improved diagnostic apparatus as described in claim 16 wherein the indicator lights are LED's.

18. The improved diagnostic apparatus as described in claim 16 wherein the indicator lights are incandescent lights.
